(19) United States
(12) Patent Application Publication
(10) Pub. No.: US 2009/0021126 A1
(43) Pub. Date: Jan. 22, 2009

(54) Display panel

(75) Inventors: Miao-Tzu Chou, Taipei Hsien (TW); Chia-Yen Hsu, Taipei Hsien (TW); Sheng-Chih Yang, Taipei Hsien (TW)

Correspondence Address: BIRCH STEWART KOLASCH & BIRCH, PO BOX 747, FALLS CHURCH, VA, 22040-0747, US

(73) Assignee: DATAVAN INTERNATIONAL CORP.

(21) Appl. No.: 11/826,759

(22) Filed: Jul. 18, 2007

(51) Int. Cl. H05K 5/03

(52) U.S. Cl. 312/223.1

(57) ABSTRACT

A display panel is disclosed having a panel frame that holds cooling fans in an accommodation opening thereof and is provided with a locating groove and an engagement structure around the accommodation opening, a cover frame that has a locating flange fitted into the locating groove of the panel frame and an engagement structure detachably fastened to the engagement structure of the panel frame by hand without tools to lock the cover frame to the panel frame and ventilation ports corresponding to the cooling fans in the accommodation opening of the panel frame, filter members respectively mounted in the ventilation ports and held in place by respective positioning members for removing dust from air passing through.

### BACKGROUND OF THE INVENTION

1. Field of the Invention

The present invention relates to display panels and more particularly, to such a display frame that can be dismounted by hand without tools so that the worker or user can clean or repair the internal cooling fans conveniently.

2. Description of the Related Art

Following fast development of high technology, many high resolution and compact display panels have been created. These sophisticated display panels generate a big amount of heat during operation. Excessive high temperature in a display panel may cause ionized electrons and thermal stress, lowering the stability of the performance of the display panel and shortening the working life of the display panel. Therefore, it is important to dissipate heat during the operation of a display panel. Many commercial display panels use cooling fans to dissipate heat. The cooling fans may be designed to draw outside cooling air into the display panel or inside air out of the display panel, causing a circulation of air through display panel so as to lower the temperature inside the display panel.

FIG. 10 shows the frame structure of a display panel according to the prior art. According to this design, the display panel has two accommodation open chambers A1 in a back cover shell A, two cooling fans B respectively mounted in the accommodation open chambers A1, and two grilles A2 that cover the accommodation open chambers A1 respectively. According to this design, the internal electronic devices of the display panel tend to be covered with dust after a long use. Accumulation of dust will affect the performance of the internal electronic devices of the display panel and the cooling fans, lowering the heat dissipation effect of the display panel. Further, the back cover shell A is affixed to the front cover shell (not shown) of the display panel with mounting screws A3. It is complicated to mount/dismount the mounting screws A3. When cleaning or repairing of the cooling fans B is necessary, the worker or user must use a hand tool, for example, screwdriver to remove the mounting screws A3 so that the back cover shell A can be separated from the front cover shell.

Therefore, it is desirable to provide a display panel that eliminates the aforesaid drawbacks.

### SUMMARY OF THE INVENTION

The present invention has been accomplished under the circumstances in view. It is therefore the main object of the present invention to provide a display panel, which is quickly detachable by hands without tools for easy cleaning or replacement of the internal parts. It is another object of the present invention to provide a display panel, which eliminates accumulation of dust, enhancing heat dissipation operation of the cooling fans.

According to one aspect of the present invention, the display panel comprises a panel frame that holds cooling fans in an accommodation opening thereof and is provided with a locating groove and an engagement structure around the accommodation opening, a cover frame that has a locating flange fitted into the locating groove of the panel frame and an engagement structure detachably fastened to the engagement structure of the panel frame by hand without tools to lock the cover frame to the panel frame and ventilation ports corresponding to the cooling fans in the accommodation opening of the panel frame, filter members respectively mounted in the ventilation ports and held in place by respective positioning members for removing dust from air passing through.

According to another aspect of the present invention, the engagement structure of the panel frame comprises a plurality of engagement grooves and a plurality of engagement flanges for engagement with the engagement structure of said cover frame, and the engagement structure of the cover frame comprises a plurality of retaining members and hooks for engagement with the engagement flanges and the engagement grooves of the engagement structure of the panel frame.

According to still another aspect of the present invention, the engagement structure of the cover frame comprises multiple pairs of splits vertically formed on the periphery thereof and the retaining members are protruded from the periphery of the cover frame and respectively suspending in between each pair of the splits for engagement with the engagement structure of the panel frame.

According to still another aspect of the present invention, the positioning members have hooks and retaining blocks respectively detachably hooked in respective retaining notches around the ventilation ports. Therefore, the positioning members can easily be disengaged from the cover frame when cleaning or replacement of the filter members is necessary.

According to still another aspect of the present invention, magnetically attractive devices may be used to detachably secure the cover frame to the panel frame.

### BRIEF DESCRIPTION OF THE DRAWINGS

FIG. 1 is an elevational view of a display panel in accordance with a first embodiment of the present invention.

FIG. 2 is an exploded view of the display panel in accordance with the first embodiment of the present invention.

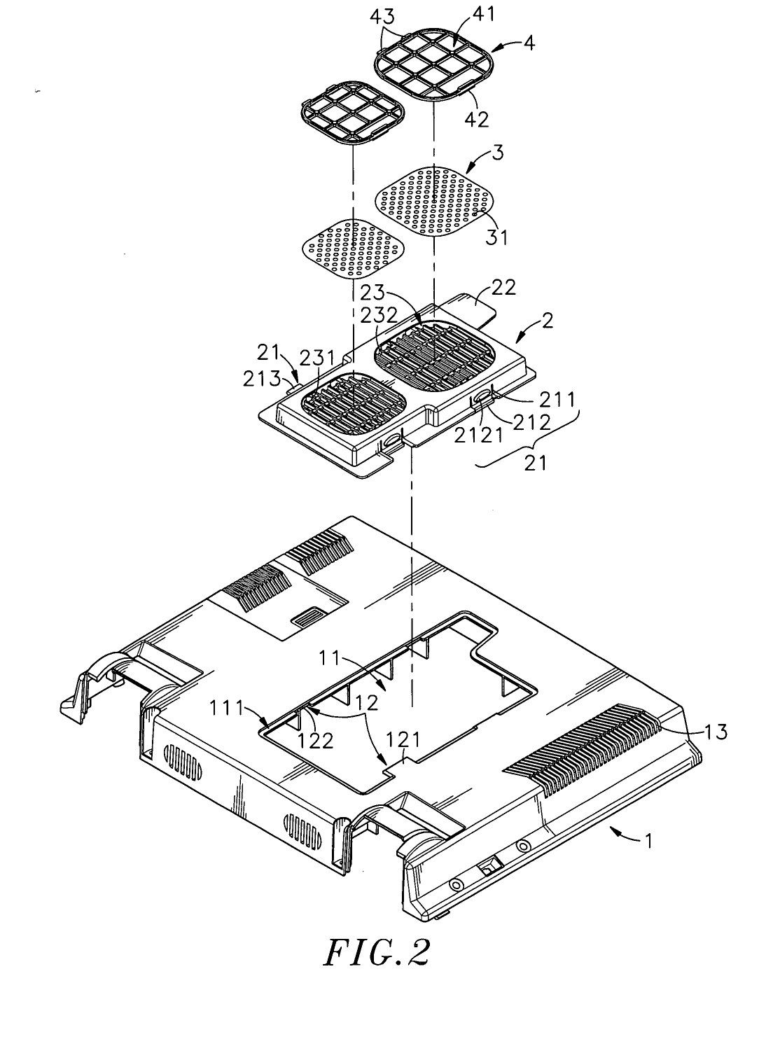

FIG. 3 is a schematic sectional side view of the display panel in accordance with the first embodiment of the present invention.

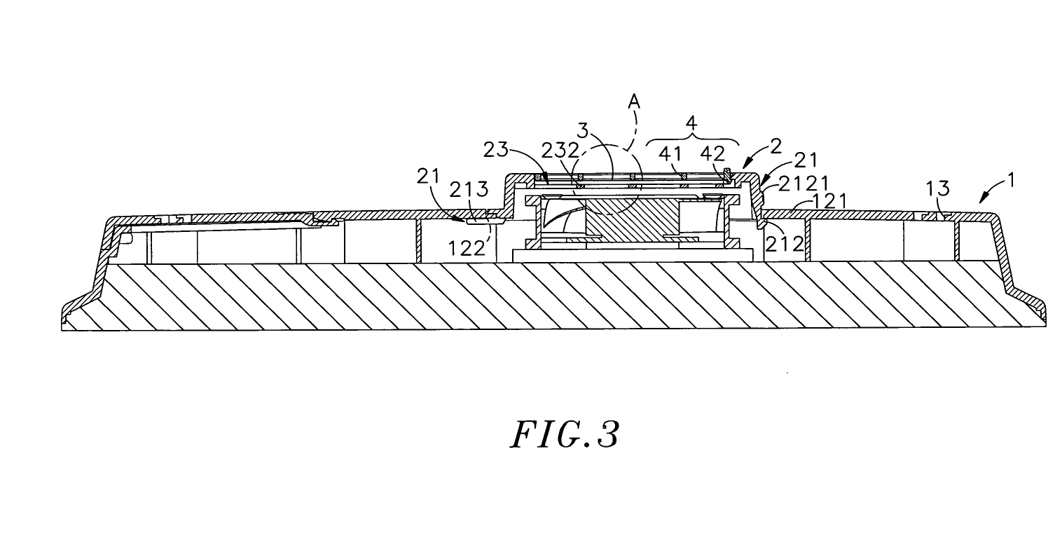

FIG. 4 is an enlarged view of part A of FIG. 3.

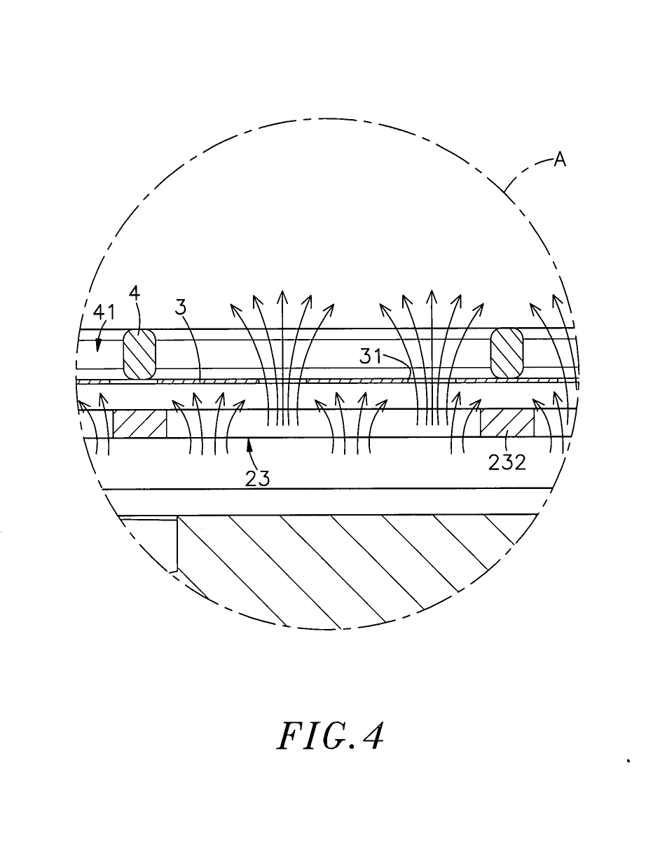

FIG. 5 is a sectional side view of the display panel in accordance with the first embodiment of the present invention after installation.

FIG. 6 corresponds to FIG. 5, showing the cover frame opened from the panel frame.

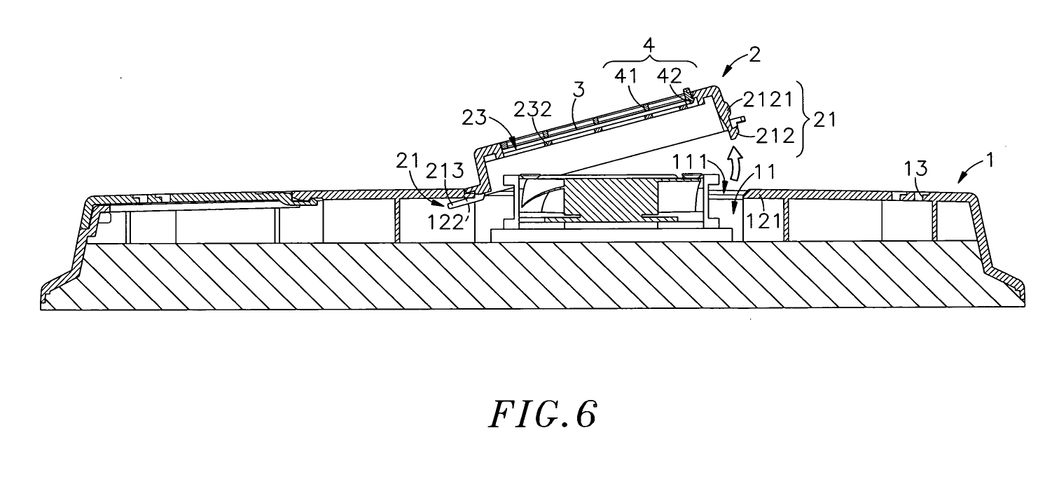

FIG. 7 corresponds to FIG. 6, showing the cover frame removed from the panel frame.

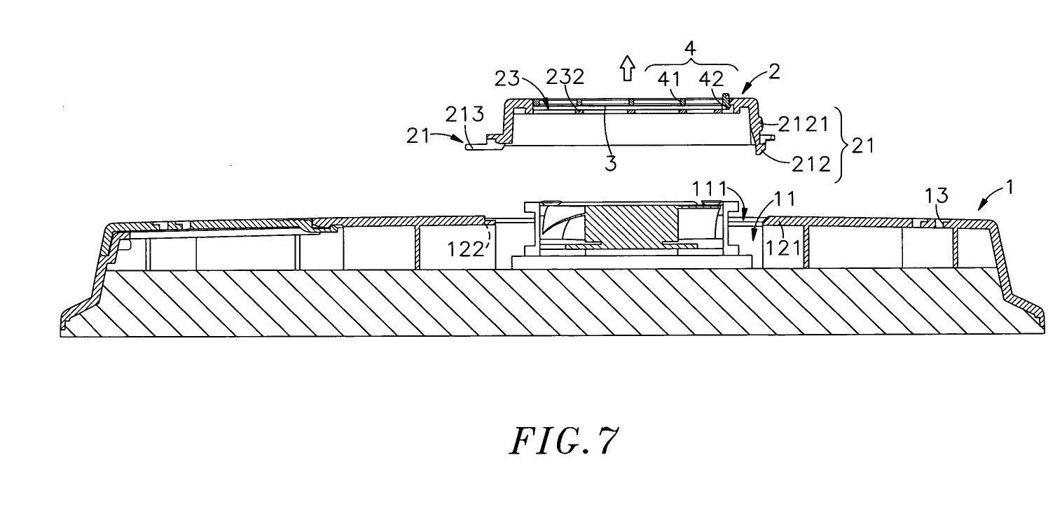

FIG. 8 is an exploded view of a display panel in accordance with a second embodiment of the present invention.

FIG. 9 is an exploded view of a display panel in accordance with a third embodiment of the present invention.

FIG. 10 shows the frame structure of a display panel according to the prior art.

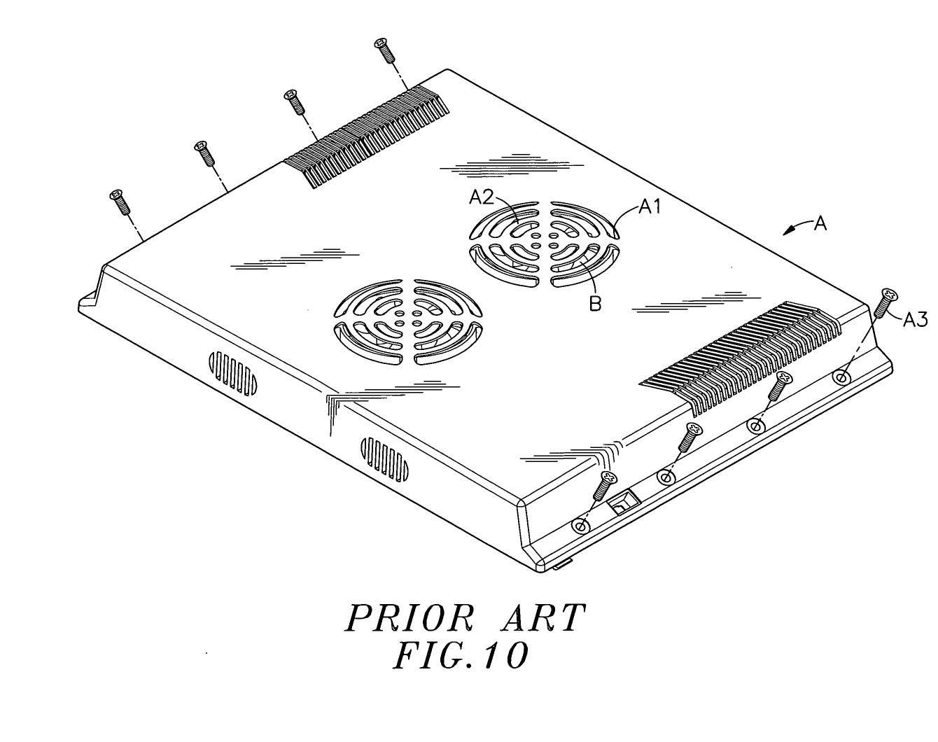

### DETAILED DESCRIPTION OF THE INVENTION

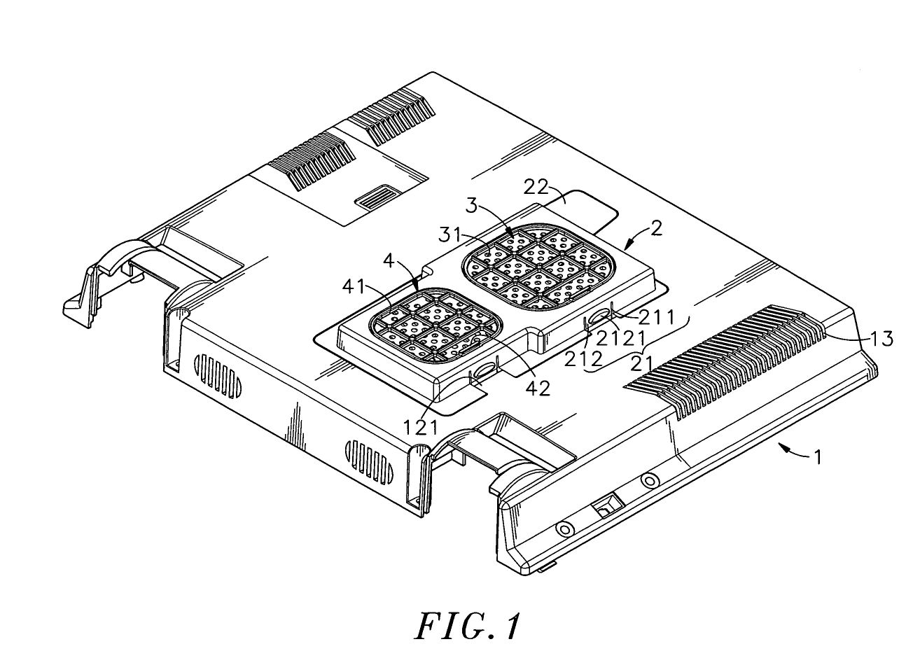

Referring to FIGS. 1˜4, a display panel in accordance with a first embodiment of the present invention is shown comprising a panel frame 1, a cover frame 2, filter members 3 and positioning members 4.

The panel frame 1 has an accommodation opening 11 adapted to accommodate at least one, for example, two cooling fans (not shown), a locating groove 111 extending around the opening 11, an engagement structure 12, and a plurality of air vents 13. The engagement structure 12 comprises a plurality of engagement flanges 121 and a plurality of engagement grooves 122.

The cover frame 2 comprises an engagement structure 21 for engagement with the engagement structure 12 of the panel frame 1, a locating flange 22 extending around the periphery and fitted into the locating groove 111 of the panel 1, and two ventilation ports 23 corresponding to the two cooling fans accommodated in the accommodation opening 11. The engagement structure 21 comprises pairs of parallel splits 211 vertically formed on the periphery at two opposite sides and extending to the bottom edge, a plurality of retaining members 212 protruded from the periphery and respectively suspending in between each pair of parallel splits 211, and a plurality of hooks 213 protruded from the periphery. The retaining members 212 each have a finger block 2121. Further, each ventilation port 23 is mounted with crossed grilles 232, and has a plurality of retaining notches 231 around the border.

The filter members 3 are respectively fastened to the ventilation ports 23 of the cover frame 2, each having a plurality of meshes 31.

The positioning members 4 are respectively fastened to the ventilation ports 23 to hold down the filter members 3, each having a plurality of open spaces 41 and a plurality of hooks 42 and retaining blocks 43 respectively fastened to the retaining notches 231 of the ventilation ports 23 of the cover frame 2.

During installation, the cooling fans (not shown) are mounted in the accommodation opening 11 of the panel frame 1, and then the cover frame 2 is set in the locating groove 111 of the panel frame 1 to force the engagement structure 21 into engagement with the engagement structure 12 of the panel frame 1, and then the filter members 3 are respectively covered on the ventilation ports 23 of the cover frame 2, and then the positioning members 4 are fastened to the ventilation ports 23 of the cover frame 2 to hold down the filter members 3.

When installed, the retaining members 212 and the hooks 213 of the engagement structure 21 of the cover frame 2 are respectively engaged with the engagement flanges 121 and the engagement grooves 122 of the panel frame 1, securing the cover frame 2 firmly to the panel frame 1; the hooks 42 and the retaining blocks 43 of the positioning members 4 are respectively fastened to the retaining notches 231 of the ventilation ports 23 of the cover frame 2, securing the positioning members 4 firmly to the cover frame 2.

During operation of the display panel, the cooling fans draw outside cooling air into the inside of the display panel or draw inside hot air out of the display panel (subject to the type of the cooling fans used) through the open spaces 41 in the positioning members 4, and the meshes 31 of the filter members 3 and the ventilation ports 23 of the cover frame 2. At this time, the filter members 3 remove solid matters from air passing through. Therefore, the cooling fans run smoothly and stably, and heat is quickly carried away from the display panel during its operation.

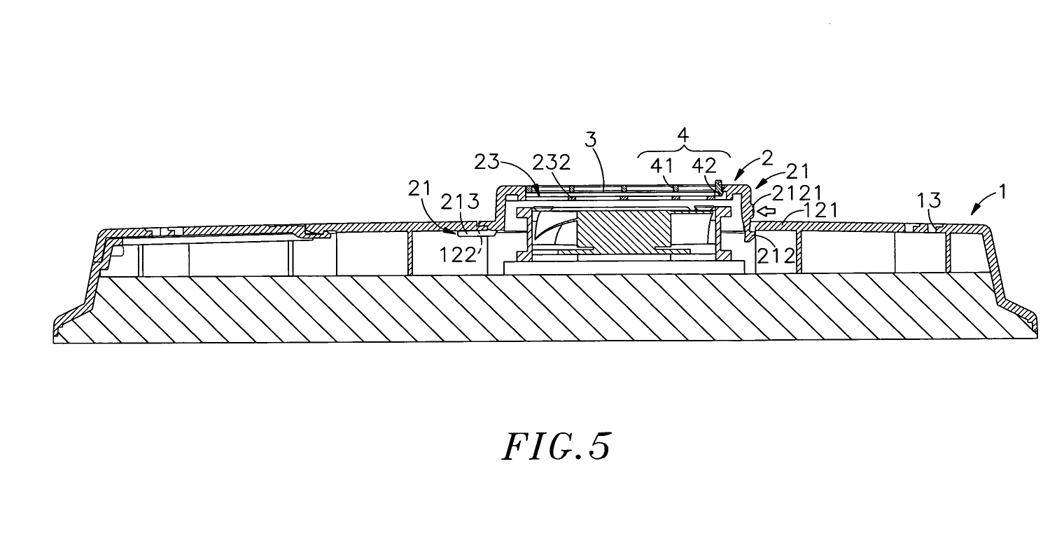

Referring to FIGS. 5˜7, the detachment of the display panel is easy and outlined hereinafter. At first, press the finger blocks 2121 to disengage the retaining members 212 from the engagement flanges 121 of the panel frame 1, and then move the cover frame 2 to disengage the hooks 213 from the associating engagement grooves 122, for allowing removal of the cover frame 2 from the panel frame 1. Because of the design of the splits 211, the retaining members 212 can be temporarily deformed and disengaged from the associating engagement flanges 121. This arrangement allows dismounting of the cover frame 2 from the panel frame 1 directly by hands without tools. After removal of the cover frame 2 from the panel frame 1, the user can clean or repair the cooling fans conveniently.

Further, by means of applying a pressure to the hooks 42 and the retaining blocks 43 of the positioning members 4 in direction away from the retaining notches 231 of the ventilation ports 23 of the cover frame 2, the positioning members 4 can easily be removed from the ventilation ports 23 of the cover frame 2 so that the filter members 3 can be removed from the ventilation ports 23 of the cover frame 2 for cleaning or replacement. The filtering effect of the filter members 3 eliminates accumulation of dust on the surfaces of the electronic devices inside the panel frame 1, enhancing the heat dissipating effect of the display panel.

Preferably, two reversed cooling fans, i.e., one forced draft fan and one induced draft fan are installed to induce a circulation of air through the display panel, dissipating heat from the display panel efficiently. Further, the engagement between the locating flange 22 of the cover frame 2 and the locating groove 111 of the panel frame 1 prevents displacement of the cover frame 2 relative to the panel frame 1. Further, the filter members 3 can be wire gauze filters, filter cloth elements or filter paper elements.

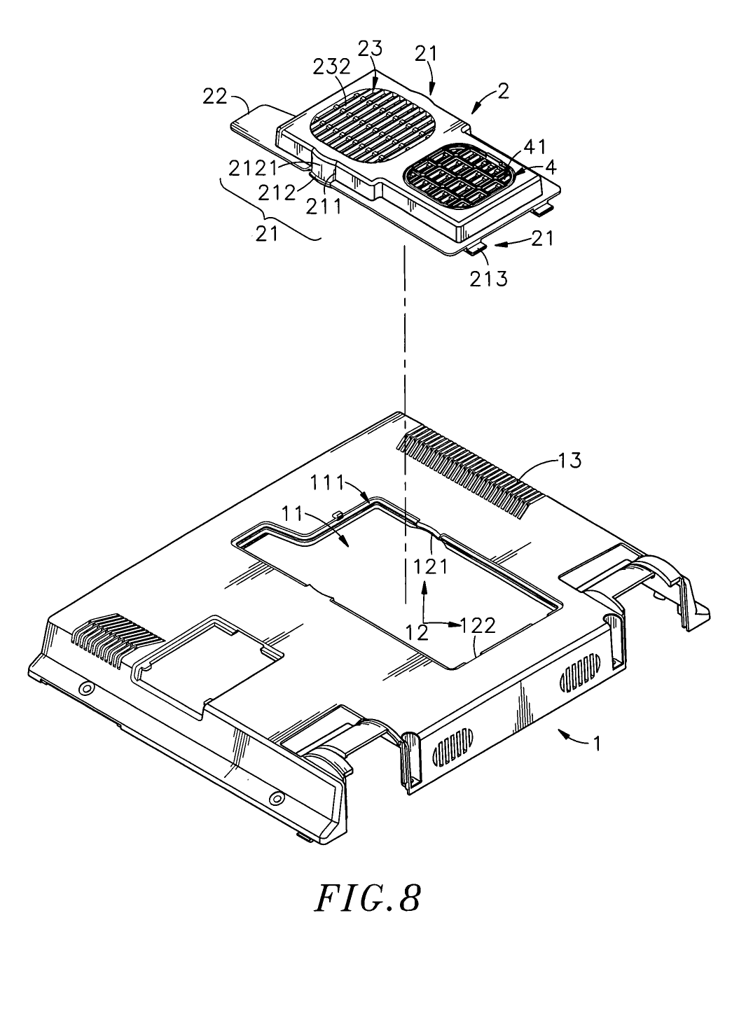

FIG. 8 is an exploded view of a display panel in accordance with a second embodiment of the present invention. This embodiment is substantially similar to the aforesaid first embodiment with the exception of the extending direction of the accommodation opening 11 in the panel frame 1, the locations of the engagement flanges 121 and the engagement grooves 122 of the engagement structure 12 at the panel frame 1, and the locations of the retaining members 212 and the hooks 213 of the engagement structure 21 at the cover frame 2.

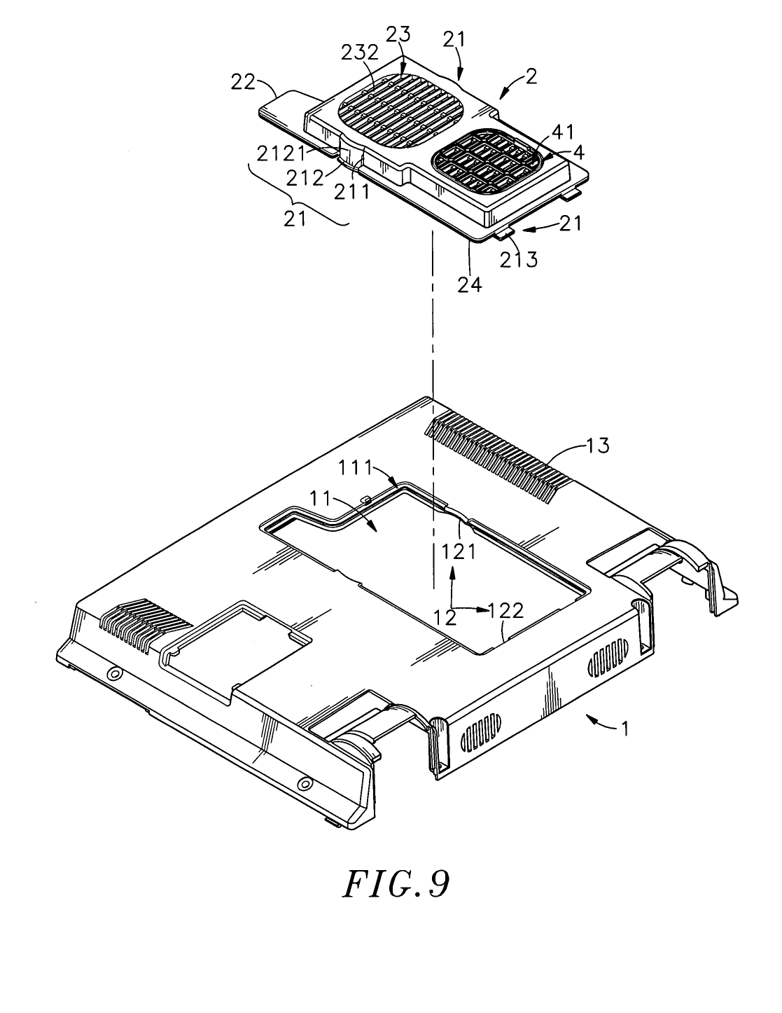

FIG. 9 is an exploded view of a display panel in accordance with a third embodiment of the present invention. This embodiment is substantially similar to the aforesaid second embodiment with the exception that magnetically attractive devices 24 are provided between the cover frame 2 and the panel frame 1 for securing the cover frame 2 to the panel frame 1 firmly in place by means of magnetic attraction.

As indicated above, the invention provides a display panel that has the following features and advantages:

1. Simply by means of pressing the finger blocks 2121 to disengage the retaining members 212 from the engagement flanges 121 of the panel frame 1, the cover frame 2 is disconnected from the panel frame 1 and can be removed from the panel frame 1 for cleaning or repair. The engagement design between the cover frame 2 and the panel frame 1 allows mounting/dismounting of the cover frame 2 with the hands directly without tools. Because of the design of the splits 211, the retaining members 212 can be temporarily deformed and disengaged from the associating engagement flanges 121 easily by hand without much effort.

2. The filter members 3 remove dust from air passing through, preventing accumulation of dust on the surfaces of the electronic devices inside the display panel and enhancing the heat dissipation effect of the display panel. Further, the positioning members 4 can easily be detached from the ventilation ports 23 of the cover frame 2 so that the user can remove the filter members 3 from the ventilation ports 23 of the cover frame 2 for cleaning or replacement.

3. By means of engagement between the engagement structure 21 of the cover frame 2 and the engagement structure 12 of the panel frame 1 and engagement between the hooks 42 and the retaining blocks 43 of the positioning members 4 and the retaining notches 231 of the cover frame 2, the installation of the present invention is easy without screws.

4. The engagement between the locating flange 22 of the cover frame 2 and the locating groove 111 of the panel frame 1 ensures tight connection between the cover frame 2 and the panel frame 1, preventing displacement of the cover frame 2 relative to the panel frame 1.

5. Cooling fans are provided to draw outside cooling air into the inside of the display panel and inside hot air out of the display panel, and therefore heat can quickly be carried out of the display panel during the operation of the display panel.

6. Magnetically attractive devices 24 may be provided between the cover frame 2 and the panel frame 1 for securing the cover frame 2 to the panel frame 1 firmly in place by means of magnetic attraction.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A display panel comprising:
a panel frame, said panel frame comprising an accommodation opening for accommodating at least one cooling fan, a locating groove extending around said accommodation opening, and an engagement structure;
a cover frame covering said accommodation opening, said cover frame comprising a locating flange fitted into said locating groove, an engagement structure engaging the engagement structure of said panel frame to lock said cover frame to said panel frame, at least one ventilation port corresponding to the at least one cooling fan mounted in said accommodation opening, and a plurality of retaining notches around said at least one ventilation port;
air filter means mounted in said at least one ventilation port; and
positioning means fastened to said retaining notches of said cover frame to hold down said filter means.

2. The display panel as claimed in claim 1, wherein the engagement structure of said panel frame comprises a plurality of engagement grooves and a plurality of engagement flanges for engagement with the engagement structure of said cover frame.

3. The display panel as claimed in claim 1, wherein the engagement structure of said cover frame comprises a plurality of retaining members and hooks for engagement with the engagement structure of said panel frame.

4. The display panel as claimed in claim 1, wherein the engagement structure of said cover frame comprises multiple pairs of splits vertically formed on the periphery of said cover frame, a plurality of retaining members protruded from the periphery of said cover frame and respectively suspending in between each pair of the splits for engagement with the engagement structure of said panel frame, and a finger block.

5. The display panel as claimed in claim 1, wherein the engagement structure of said cover frame comprises a plurality of hooks extending from the periphery of said cover frame for engagement with the engagement structure of said panel frame.

6. The display panel as claimed in claim 1, wherein said at least one ventilation port of said cover frame has a plurality of crossed grilles.

7. The display panel as claimed in claim 1, wherein said filter means comprises at least one wire gauze filter respectively mounted in said at least one ventilation port.

8. The display panel as claimed in claim 1, wherein said filter means comprises at least one filter cloth elements respectively mounted in said at least one ventilation port.

9. The display panel as claimed in claim 1, wherein said filter means comprises at least one filter paper elements respectively mounted in said at least one ventilation port.

10. The display panel as claimed in claim 1, wherein said positioning means comprises a plurality of open spaces and a plurality of hooks and retaining blocks respectively fastened to the retaining notches of said cover frame.

11. The display panel as claimed in claim 1, further comprising a plurality of magnetically attractive devices respectively provided at said cover frame and said panel frame for securing said cover frame to said panel frame.
